(19) United States
(12) Patent Application Publication
(10) Pub. No.: US 2024/0306462 A1
(43) Pub. Date: Sep. 12, 2024

(54) DISPLAY PANEL AND DISPLAY APPARATUS

(71) Applicant: BOE Technology Group Co., Ltd., Beijing (CN)

(72) Inventors: Jian GAO, Beijing (CN); Sen MA, Beijing (CN); Wenji ZHU, Beijing (CN)

(21) Appl. No.: 18/273,044

(22) PCT Filed: Aug. 23, 2022
(86) PCT No.: PCT/CN2022/114341

§ 371 Date: Jul. 19, 2023

(30) Foreign Application Priority Data
Sep. 30, 2021 (CN) 202111162175.9

(51) Int. Cl. H10K 59/35; H10K 59/38; H10K 59/80

(52) U.S. Cl. CPC H10K 59/353; H10K 59/38; H10K 59/879

(57) ABSTRACT

The present disclosure provides a display panel and a display apparatus. The display panel includes a pixel array layer and a lens array layer. The lens array layer includes micro-lenses arranged along a first direction. The pixel array layer includes pixel islands, each of the pixel islands includes sub-pixel islands arranged along a second direction; each of the sub-pixel islands is divided into sub-pixel groups arranged in the first direction. For two adjacent pixel islands in the first direction, an opaque region is provided in at least one sub-pixel group in an adjacent region of the two adjacent pixel islands, a width of the opaque region is greater than a width of a gap between two adjacent sub-pixels in other sub-pixel groups in a same pixel island. In a same sub-pixel island, gaps between sub-pixels in a sub-pixel group are correspondingly complemented by sub-pixels in other sub-pixel groups.

### TECHNICAL FIELD

The present disclosure relates to the field of display technology, and in particular, to a display panel and a display apparatus.

### BACKGROUND

Auto-stereoscopy 3D display technology is a technology that enables people to have a stereoscopic vision without aid of auxiliary tools. Principle of the auto-stereoscopy 3D display technology is binocular parallax imaging, that is, left and right eyes of a viewer receive slightly different images respectively, and after being analysed and integrated by the brain, the slightly different images are fused into a perfect scene, so that the viewer can perceive a depth of objects in the picture, and then stereoscopic impression is generated. 3D display technology improves display effect and comfort of viewers.

In related arts, an organic light-emitting diode (OLED) manufactured based on a color filter film manner (WOLED+CF) is subdivided into sub-pixels in a row direction (X direction), and through specific structural design, continuous visual space of 3D display is achieved and Moire pattern is eliminated.

However, for organic light-emitting diodes (OLED) with higher light-emitting efficiency manufactured based on a fine metal mask (FMM) process, due to limitation of the manufacturing process, using a same pixel structure with a same optical design will result in voids in some viewing angles, thereby causing Moire patterns and influencing display effect.

### SUMMARY

The present disclosure provides a display panel, to achieve continuous visual space for auto-stereoscopy 3D display.

According to an embodiment of the present disclosure, a display panel is provided, where the display panel includes a pixel array layer and a lens array layer arranged in a stacked manner; where
the lens array layer includes micro-lenses arranged along a first direction;
the pixel array layer includes pixel islands arranged in an array layout, each of the pixel islands includes sub-pixel islands arranged along a second direction, each of the sub-pixel islands includes sub-pixels, and the sub-pixels in a same sub-pixel island have a same luminous color; each of the sub-pixel islands is divided into sub-pixel groups arranged in the first direction, and for each of the sub-pixel groups, an orthographic projection of the sub-pixel group on the lens array layer falls within a corresponding micro-lens;
for two adjacent pixel islands in the first direction, an opaque region is provided in at least one sub-pixel group in an adjacent region of the two adjacent pixel islands, a width of the opaque region in the first direction is greater than a width of a gap between two adjacent sub-pixels in other sub-pixel groups in a same pixel island; and
in a same sub-pixel island, gaps between sub-pixels in a sub-pixel group are correspondingly complemented by the sub-pixels in other sub-pixel groups.

In an embodiment, in a same sub-pixel island, positions of, a quantity of and a sum of widths of the gaps in one of the sub-pixel groups are correspondingly same as positions of, a quantity of and a sum of widths of the sub-pixels in other two sub-pixel groups respectively.

In an embodiment, each of the sub-pixel islands includes three sub-pixel groups arranged in the first direction: a first sub-pixel group, a second sub-pixel group and a third sub-pixel group, where the second sub-pixel group is located between the first sub-pixel group and the third sub-pixel group, and the third sub-pixel group includes or does not include the sub-pixels.

In an embodiment, the opaque region is formed in an region of the third sub-pixel group away from the second sub-pixel group, and a width of the opaque region is greater than a width of a gap between adjacent sub-pixels in the first sub-pixel group and the second sub-pixel group.

In an embodiment, the width of the opaque region≥38 μm.

In an embodiment, each of the pixel islands includes a first sub-pixel island for emitting red light, a second sub-pixel island for emitting green light and a third sub-pixel island for emitting blue light, where the first sub-pixel island, the second sub-pixel island and the third sub-pixel island are arranged along the second direction.

In an embodiment, for any two adjacent pixel islands arranged in the first direction, the first sub-pixel islands of the two adjacent pixel islands are at a same height, the second sub-pixel islands of the two adjacent pixel islands are at a same height, and the third sub-pixel islands of the two adjacent pixel islands are at a same height.

In an embodiment, for any two adjacent pixel islands arranged in the first direction and denoted as a first pixel island and a second pixel island, any two of the sub-pixel islands in the first pixel island and the second pixel island are not at a same height, and a sub-pixel island in the first pixel island is far away from a sub-pixel island with a same color in the second pixel island in a height direction.

In an embodiment, in a same pixel island, a width of a gap between two adjacent sub-pixels is equal or not equal to a width of a sub-pixel.

In an embodiment, the width of the gap between two adjacent sub-pixels≥4 μm.

In an embodiment, a material of the micro-lens includes a low refractive index resin and a high refractive index resin, where the high refractive index resin is closer to the pixel array layer than the low refractive index resin.

In an embodiment, the display panel further includes a pad layer, and the pad layer is between the pixel array layer and the lens array layer.

In an embodiment, sub-pixels in the pixel islands for emitting lights of different color are made up of different organic light-emitting materials.

According to a second aspect of embodiments of the present disclosure, a display apparatus is provided, where the display apparatus includes the display panel mentioned above.

### BRIEF DESCRIPTION OF DRAWINGS

FIG. 1 is a pixel-layout diagram of an organic light-emitting diode (OLED) based on a color filter film manner (WOLET+CF).

FIG. 2A is light path diagram of an organic light-emitting diode (OLED) based on a color filter film manner (WOLET+CF), and FIG. 2B is a partially enlarged diagram of FIG. 2A.

FIG. 3 is a pixel-layout diagram of an organic light-emitting diode (OLED) manufactured based on a fine metal mask (FMM).

FIG. 4A is a light path diagram of an organic light-emitting diode (OLED) manufactured based on a fine metal mask (FMM), and FIG. 4B is a partially enlarged diagram of FIG. 4A.

FIG. 5 is a schematic diagram of pixel islands in a display panel of an embodiment of the present disclosure.

FIG. 6 is a sectional diagram of a display panel of an embodiment of the present disclosure.

FIG. 7 is a schematic layout diagram of pixel islands in a display panel of an embodiment of the present disclosure.

FIG. 8A is a light path diagram of a display panel of an embodiment of the present disclosure, and FIG. 8B is a partially enlarged diagram of FIG. 8A.

FIG. 9 is a schematic diagram of pixel islands in a display panel of another embodiment of the present disclosure.

FIG. 10 is a schematic layout diagram of pixel islands in a display panel of another embodiment of the present disclosure.

FIG. 11A is a light path diagram of a display panel of another embodiment of the present disclosure, and FIG. 11B is a partially enlarged diagram of FIG. 11A.

### DETAILED DESCRIPTION

Description will now be made in detail to illustrative embodiments, examples of which are shown in the accompanying drawings. When the following description refers to the drawings, unless otherwise indicated, the same numbers in different drawings indicate the same or similar elements. Embodiments described in the following illustrative embodiments do not represent all embodiments consistent with the present disclosure. In contrary, they are merely examples of apparatuses and methods consistent with some aspects of the present disclosure as described in detail in the appended claims.

The terminologies used in the present disclosure are for the purpose of describing specific embodiments only and are not intended to limit the present disclosure. Singular forms “a”, “the” and “said” used in the present disclosure and the appended claims are also intended to include plural forms, unless the context clearly indicates other meaning. It should also be understood that the term “and/or” as used herein refers to and includes any or all possible combinations of one or more associated listed items.

Color filter film manner (WOLED+CF) and fine metal mask (FMM) evaporation process are common processes for manufacturing organic light emitting diodes (OLED). Color filter film manner (WOLED+CF) is generally based on manufacturing manners of white organic light-emitting diode (WOLED) combined with color filter film (CF). First, white organic light-emitting diode (WOLED) devices are manufactured, and then three primary color are obtained through color filter film (CF), and then color display is realized based on the three primary color.

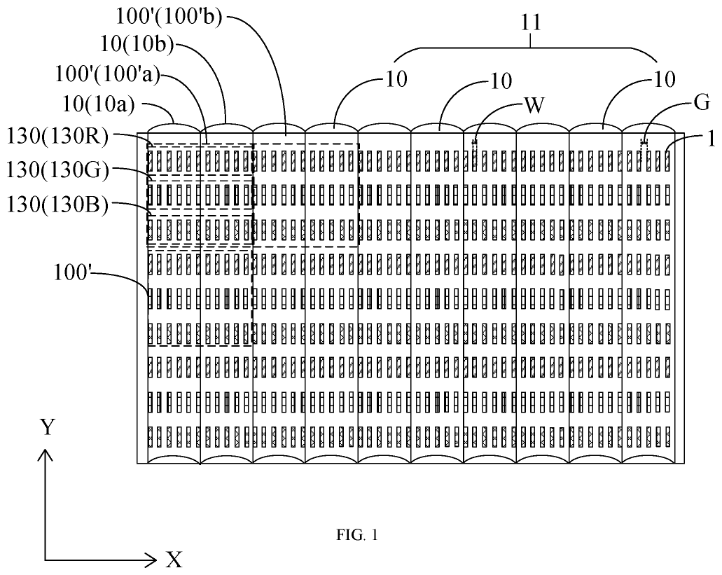

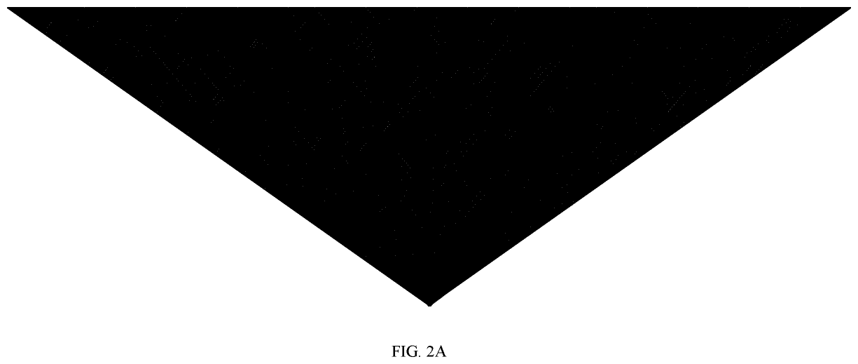

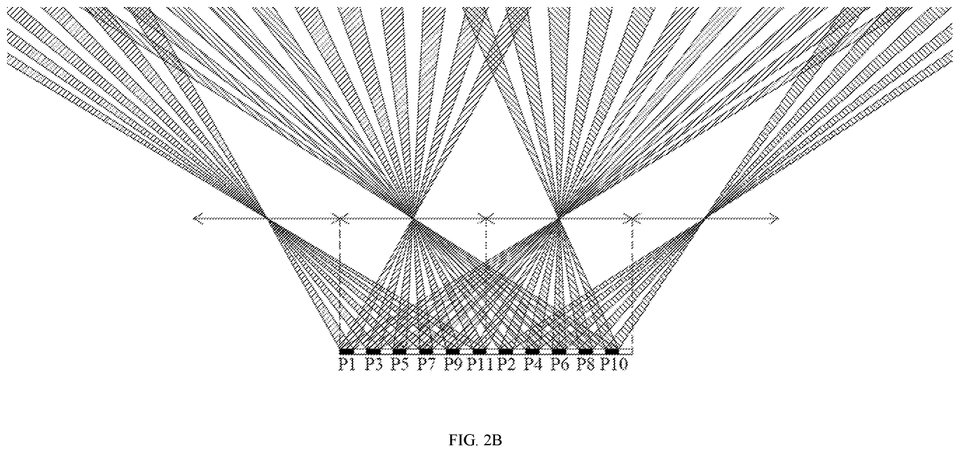

In the manufacturing process of the color filter film manner (WOLED+CF), a pixel-structure layout is shown in FIG. 1. The pixel-structure layout is consisted of pixel islands 100′ arranged in columns and a lens array layer 11, where the lens array layer 11 includes micro-lenses 10 arranged in columns. Pixel islands 100′a are a first column of pixel islands arranged along an X direction, and pixel islands 100′b are a second column of pixel islands arranged along the X direction, and so on; a micro-lens 10a is a first column of a cylindrical lens, and a micro-lens 10b is a second column of a cylindrical lens, and so on. Each of the pixel islands 100′ is divided into sub-pixels 1 in a row direction (X direction), and widths W of the respective sub-pixels 1 are equal, gaps G between the respective sub-pixels 1 are equal, and the gap G is equal to the width W of a light-emitting region of each of the sub-pixels. A width of each of the pixel island 100′ is equal to a width of two micro-lenses 10 in the lens array layer 11, and it is designed that a relative relationship between the sub pixels 1 in one pixel island 100′ and micro-lenses 10 does not constitute a repetitive unit, that is, the gaps G between adjacent sub-pixels 1 in a sub-pixel island 130R, a sub-pixel island 130G and a sub-pixel island 130B of the sub-pixel islands 130 can be correspondingly complemented by the sub-pixels 1 in other sub-pixel groups 150. That is, a sub-pixel P2, a sub-pixel P4, a sub-pixel P6, a sub-pixel P8 and a sub-pixel P10 fill in a gap between a sub-pixel P1 and a sub-pixel P3, a gap between a sub-pixel P3 and a sub-pixel P5, a gap between a sub-pixel P5 and a sub-pixel P7, a gap between a sub-pixel P7 and a sub-pixel P9, and a gap between a sub-pixel P9 and a sub-pixel P11 in sequence respectively. A final light path diagram is shown in FIGS. 2A and 2B, where FIG. 2B is a partially enlarged diagram of FIG. 2A. It is noted that with such pixel layout, light-emitting regions of sub-pixels are mutually intersected and complemented relative to two cylindrical lens units, so that light-emitting directions of the sub-pixels is continuous in a visual space of 3D display, and Moire pattern is eliminated.

Compared to organic light-emitting diodes (OLED) manufactured based on the color filter film manner (WOLED+CF), organic light-emitting diodes (OLED) manufactured based on fine metal mask (FMM) evaporation process have higher light-emitting efficiency.

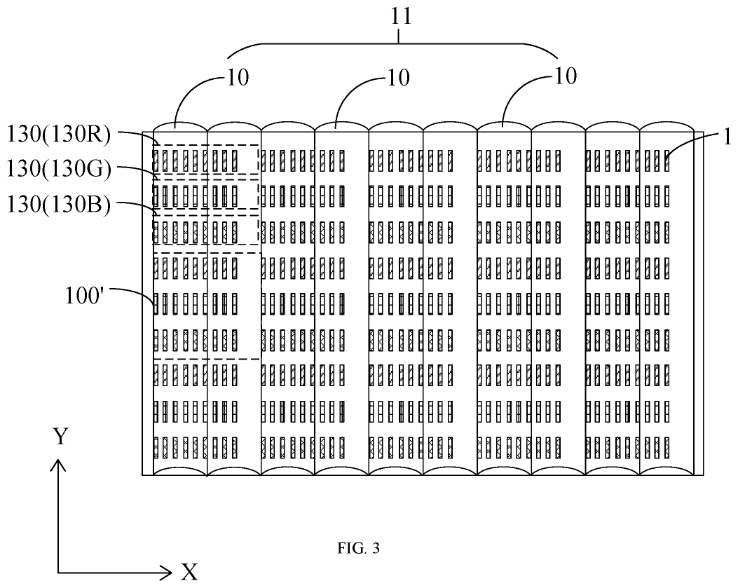

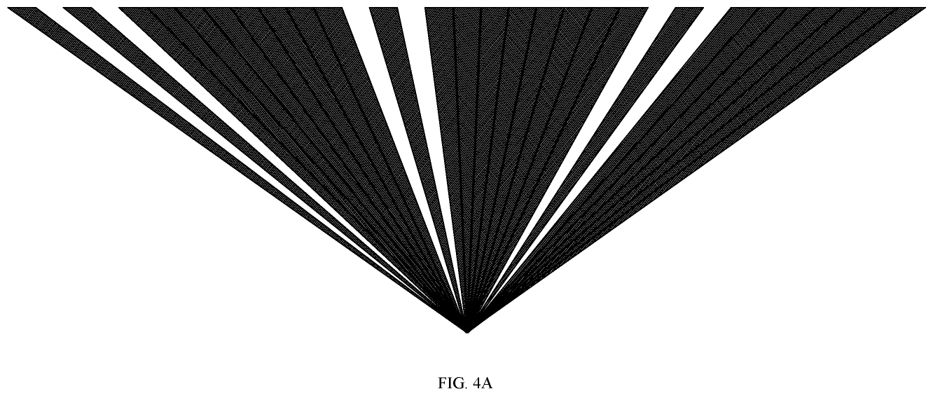

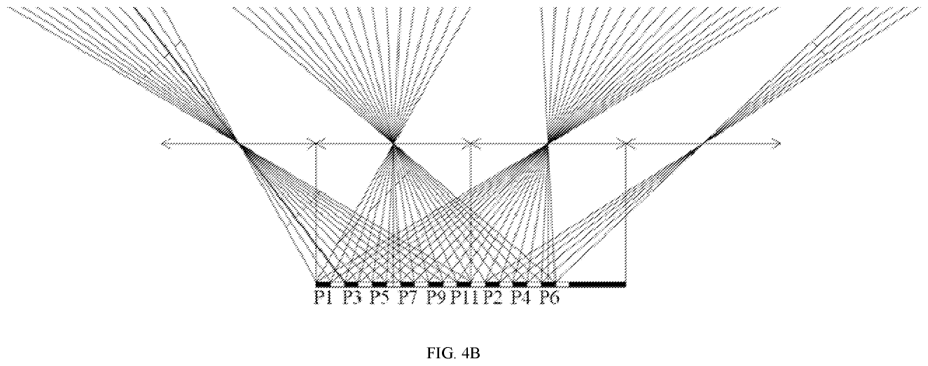

However, the process of manufacturing organic light emitting diodes (OLED) based on fine metal mask (FMM) has certain requirements. If the same optical design and same pixel structure are adopted as the color filter film manner (WOLED+CF) process, the pixel-structure layout is shown in FIG. 3, it is noted that a width of one pixel island 100′ is equal to a width of two micro-lenses 10 of the lens array layer 11, and sub-pixels 1 in the sub-pixel island 130R, the sub-pixel island 130G and the sub-pixel island 130B in the sub-pixel islands 130 cannot achieve complementation of light-emitting space in an region corresponding to the lens array layer 11. The sub-pixel P2, the sub-pixel P4, and the sub-pixel P6 fill in the gap between the sub-pixel P1 and the sub-pixel P3, the gap between the sub-pixel P3 and the sub-pixel P5, the gap between the sub-pixel P5 and the sub-pixel P7 in sequence respectively. However, the gap between the sub-pixel P7 and the sub-pixel P9, and the gap between the sub-pixel P9 and the sub-pixel P11 are not filled. Correspondingly, the light path is shown in FIGS. 4A and 4B, where FIG. 4B is a partially enlarged diagram of FIG. 4A. Voids will occur in some viewing angles, resulting in Moire patterns, and effect of continuous visual space of auto-stereoscopy 3D display as organic light-emitting diodes (OLED) manufactured based on the color filter film manner (WOLED+CF) cannot be achieved.

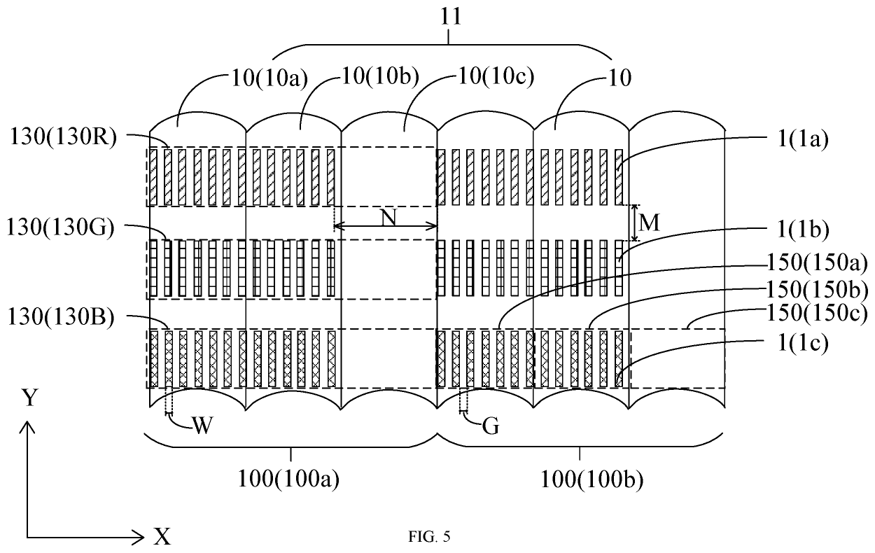

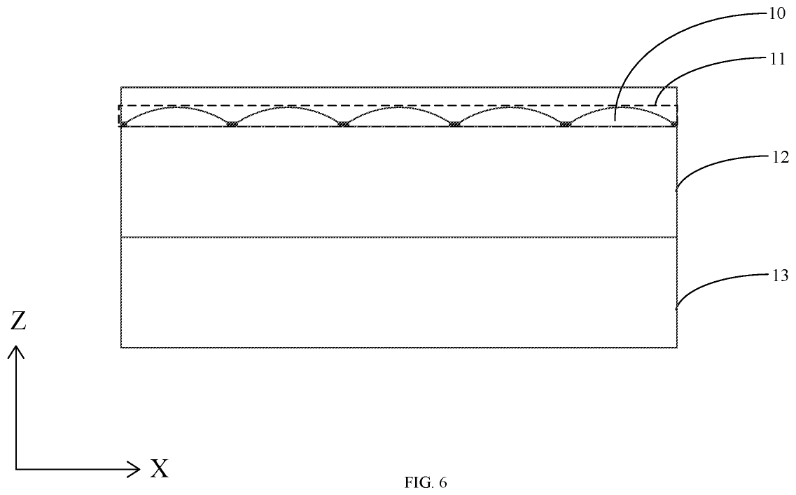

To solve the above problems, an embodiment of the present disclosure provides a display panel, as shown in FIGS. 5, 6 and 7, where the display panel includes a pixel array layer 13 and a lens array layer 11 arranged in a stacked manner. The pixel array layer 13 and the lens array layer 11 are arranged in a stacked manner in a third direction Z (a deposition direction of layers), and are at different depths. The lens array layer 11 includes micro-lenses 10 arranged along a first direction X (a row direction).

The pixel array layer 13 includes pixel islands 100 arranged in an array layout, each of the pixel islands 100 includes sub-pixel islands 130 arranged in a second direction Y (a column direction), and each of the sub-pixel islands 130 includes sub-pixels 1. The sub-pixels 1 in one sub-pixel island 130 have a same luminous color. Each of the sub-pixel islands 130 is divided into sub-pixel groups 150 arranged along the first direction X, where the sub-pixels in the sub-pixel islands 130 are correspondingly classified into the sub-pixel groups 150, for each of the sub-pixel groups 150, an orthographic projection of the sub-pixel group 150 on the lens array layer 11 falls within a corresponding micro-lens 10.

In one sub-pixel island 130, gaps G between sub-pixels 1 in a sub-pixel group 150 are correspondingly complemented by the sub-pixels 1 in other sub-pixel groups 150.

Due to process limitation, each of the sub-pixel groups 150 cannot emit light continuously. In an embodiment of the present disclosure, the sub-pixels 1 of other sub-pixel groups 150 in a same sub-pixel island 130 are used to fill in light-emitting gaps in a current sub-pixel group 150, so that the sub-pixel group 150 with discontinuous light emission is equivalent to a pixel structure with continuous light emission. Therefore, the above arranged pixel array layer 13 can achieve 3D continuous display effect after passing through the micro-lenses 10 of the lens array layer 11.

FIG. 5 illustratively shows two adjacent pixel islands 100 in one row: a pixel island 100a and a pixel island 100b. Each of the pixel islands 100 has a same structure, and the pixel island 100a is taken as an example to describe the structure. The pixel island 100a includes three sub-pixel islands 130: a first sub-pixel island 130R, a second sub-pixel island 130G and a third sub-pixel island 130B. The first sub-pixel island 130R, the second sub-pixel island 130G and the third sub-pixel island 130B are arranged along the column direction Y in sequence. The first sub-pixel island 130R is used to emit red light, the second sub-pixel island 130G is used to emit green light, and the third sub-pixel island 130B is used to emit blue light. Correspondingly, sub-pixels 1 included in the first sub-pixel island 130R, the second sub-pixel island 130G and the third sub-pixel island 130B have different light-emitting materials. Sub-pixels 1a of the first sub-pixel island 130R have an organic light-emitting material for emitting red light, sub-pixels 1b of the second sub-pixel island 130G have an organic light-emitting material for emitting green light, sub-pixels 1c of the third sub-pixel island 130B have an organic light-emitting material for emitting blue light. Therefore, when performing evaporation of organic light-emitting materials in the fine metal mask (FMM) evaporation process, three times of evaporation processes are needed, and an organic light-emitting material of one light-emitting color is evaporated for each time.

For any two adjacent pixel islands 100 in one row, sub-pixel islands 130 for emitting light of a same color are at a same height in the column direction Y. By taking FIG. 5 as an example, the first sub-pixel island 130R for emitting red light in the pixel island 100a and the first sub-pixel island 130R for emitting red light in the pixel island 100b are at a same height; the second sub-pixel island 130G for emitting green light in the pixel island 100a and the second sub-pixel island 130G for emitting green light in the pixel island 100b are at a same height; the third sub-pixel island 130B for emitting blue light in the pixel island 100a and the third sub-pixel island 130B for emitting blue light in the pixel island 100b are at a same height.

Configurations, other than light color, of the first sub-pixel island 130R, the second sub-pixel island 130G and the third sub-pixel island 130B are same. A structure of a sub-pixel island 130 will be described below by taking any sub-pixel island 130 as an example.

Each of the sub-pixel islands 130 includes three sub-pixel groups 150 arranged along the row direction X: a first sub-pixel group 150a, a second sub-pixel group 150b and a third sub-pixel group 150c. The second sub-pixel group 150b is located between the first sub-pixel group 150a and the third sub-pixel group 150c. A number of sub-pixels 1 may be different in respective sub-pixel groups 150a, 150b and 150c. Sub-pixels 1 may even not be provided in some sub-pixel groups 150. In FIG. 5, seven sub-pixels 1 and six gaps (each of the gaps is located between two adjacent sub-pixels) are provided in the first sub-pixel group 150a; six sub-pixels 1 and seven gaps are provided in the second sub-pixel group 150b; no sub-pixel 1 is provided in the third sub-pixel group 150c.

It shall be noted that the “gap” in the present disclosure does not refer to that a space between two sub-pixels is not filled up by any solid or liquid, the “gap” merely refers to that the two sub-pixels are not connected to each other, and the “gap” refers to a space there between. In fact, the “gap” between sub-pixels is usually filled up by opaque materials such as pixel defining layer and black matrix.

Positions and widths W of the six sub-pixels 1 in the second sub-pixel group 150b are corresponding to and equal to positions and widths G of the six gaps in the first sub-pixel group 150a respectively. A sum of widths W of the six sub-pixels 1 in the second sub-pixel group 150b is equal to a sum of widths G of the six gaps in the first sub-pixel group 150a. With such arrangement, after passing through the micro-lens 10, light emitted by the six sub-pixels 1 in the second sub-pixel group 150b can exactly fill in regions corresponding to the six gaps in the first sub-pixel group 150a, so as to achieve continuous 3D display in such regions.

Similarly, positions and widths W of the seven sub-pixels 1 in the first sub-pixel group 150a are corresponding to and equal to positions and widths G of the seven gaps in the second sub-pixel group 150b respectively. A sum of widths W of the seven sub-pixels 1 in the first sub-pixel group 150a is equal to a sum of widths G of the seven gaps in the second sub-pixel group 150b. The seven sub-pixels 1 in the first sub-pixel group 150a correspond to the seven gaps in the second sub-pixel group 150b and can exactly fill in the seven gaps in the second sub-pixel group 150b.

Similarly, the seven sub-pixels 1 in the first sub-pixel group 150a and the six sub-pixels 1 in the second sub-pixel group 150b can exactly and correspondingly complement an entire region of the third sub-pixel group 150c.

As mentioned above, when forming sub-pixels 1 based on fine metal mask (FMM) evaporation, it is necessary to set a large distance between sub-pixels 1 emitting a same color in adjacent pixel islands, and a position and a space corresponding to this large distance will usually be filled up with opaque materials (such as pixel defining layer materials or black matrix materials). Therefore, the position and region corresponding to this large distance designed according to FMM process will also be referred to as “opaque regions” herein. In FIG. 5, no sub-pixel 1 is provided in the third sub-pixel group 150c, so the entire third sub-pixel group 150c may be considered as the opaque region or a part of the opaque region. A width of the opaque region is much larger than a width G of a gap between adjacent sub-pixels 1 in a same sub-pixel island 130. The width of the opaque region is usually greater than or equal to 38 μm (micrometers), so as to achieve fine process effect.

In the display panel, shapes and sizes of respective sub-pixels 1 may be same. In one sub-pixel island 130, widths G of gaps between adjacent sub-pixels 1 may be equal, and a width G of a gap may be equal to a width W of each of the sub-pixels 1. The width G of the gap between adjacent sub-pixels 1 is usually greater than or equal to 4 μm.

Micro-lenses 10 in the lens array layer serve to shrink light-emitting angles of the sub-pixels 1, so that light-emitting directions of the sub-pixels 1 do not overlap or disturb in space. Each of the micro-lenses 10 may be a cylindrical lens, and the column direction Y is a length direction of the cylindrical lens. In the column direction, each of the micro-lenses 10 may cover a plurality of the pixel islands 100, and even may cover a whole column of the pixel islands 100.

A manufacturing process of the lens array layer 11 may include: using polyethylene terephthalate (PET), polymethyl methacrylate (PMMA) or resin material as a base material, and performing ultraviolet curing and/or embossing on the base material to obtain the required lens array layer 11 structure.

It is taken as an example that the base material is resin, the lens array layer 11 may be made up of high refractive index resin and low refractive index resin, where the high refractive index resin is on a side closer to the pixel array layer 13, and the low refractive index resin is on a side away from the pixel array layer 13.

The display panel may further include a pad layer 12, the pad layer 12 is between the pixel array layer 13 and the lens array layer 11, and the pad layer 12 is used to achieve a placement height of the lens array layer 11. The pad layer 12 is preferably light and thin plexiglass.

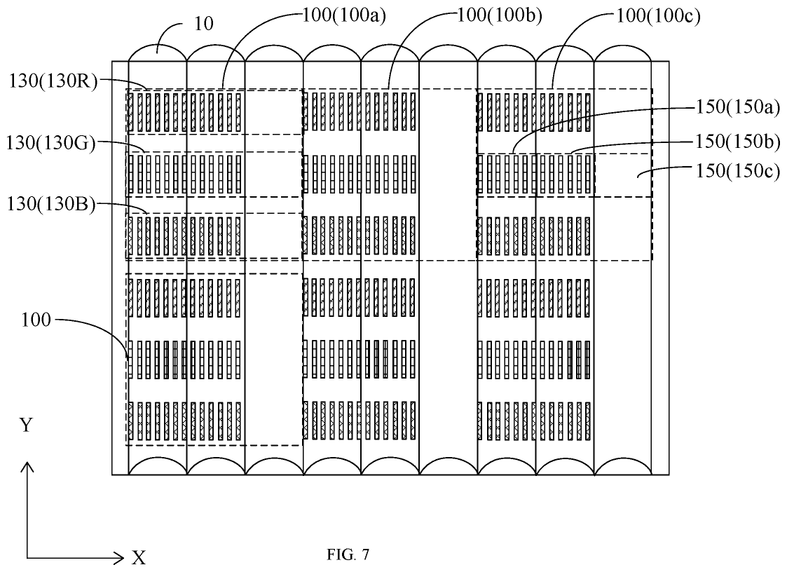

FIG. 7 shows more layouts of the pixel islands 100. Three pixel islands 100 are arranged in each row: a first pixel island 100a, a second pixel island 100b and a third pixel island 100c. A structure of each of the pixel islands 100, and a position relationship between adjacent pixel islands 100 are same as those shown in FIG. 5.

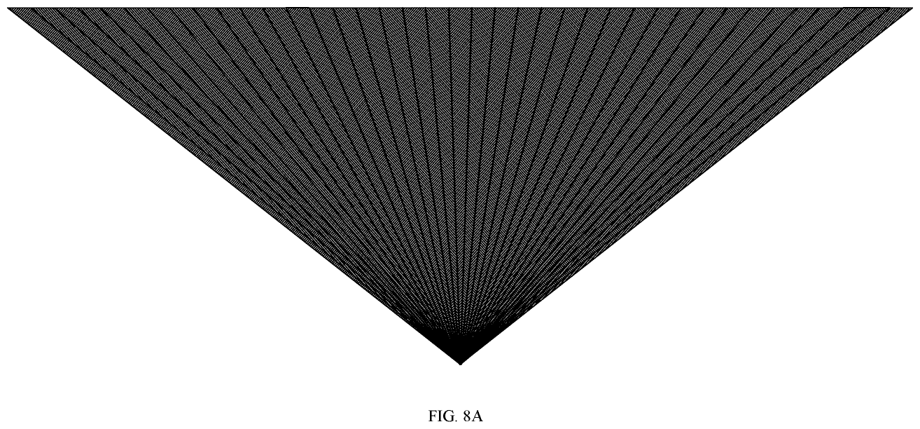

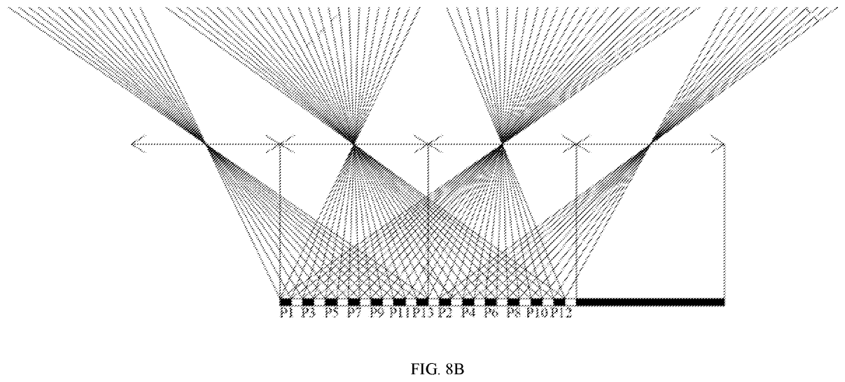

FIGS. 8A and 8B are light path diagrams of the display panels in FIGS. 5 and 7, and FIG. 8B is a partially enlarged diagram of FIG. 8A. As shown in FIGS. 8A and 8B, and with reference to FIGS. 5 and 7, the six sub-pixels 1 (sub-pixel P2, sub-pixel P4, sub-pixel P6, sub-pixel P8, sub-pixel P10 and sub-pixel P12) in the second sub-pixel group 150b fill in the six gaps (a gap between a sub-pixel P1 and a sub-pixel P3, a gap between a sub-pixel P3 and a sub-pixel P5, a gap between a sub-pixel P5 and a sub-pixel P7, a gap between a sub-pixel P7 and a sub-pixel P9, a gap between a sub-pixel P9 and a sub-pixel P11, and a gap between a sub-pixel P11 and a sub-pixel P13) in the first sub-pixel group 150a in sequence respectively. Finally, equal effect of continuous light-emitting is achieved as shown in FIGS. 8A and 8B. Such structural design of the pixel island can increase a light-covering region on edges of the pixel island 100, thereby achieving continuous light-emitting, effectively eliminating Moire patterns, and ensuring display effect.

In the above embodiments, widths M of gaps between sub-pixel islands 130 with different color in different rows are same, and are greater than a width G of a gap between adjacent sub-pixels 1.

When the layout of the pixel island array is applied to a 27-inch display panel with a resolution of 4K, a width of each of the pixel islands 100 can be designed to be 156 μm. This is determined by the final display resolution of the display panel, where the resolution is a number of pixel islands.

Accordingly, a width of each of the micro-lenses 10 is 52 μm, and a width of each of the sub-pixel groups 150 is also 52 μm.

Correspondingly, a width of a gap between adjacent sub-pixels 1 in the sub-pixel island 130 is 4 μm, which is determined by the requirement that the sub-pixel spacing in the island is ≥4 μm in the process of manufacturing organic light emitting diodes (OLED) by using fine metal masks (FMM).

Accordingly, in the sub-pixel island 130, the width W of each of the sub-pixels 1 is 4 μm, the width W is equal to the width G of the gap between adjacent sub-pixels.

In one row; a distance N between sub-pixels of adjacent pixel islands 100 is 56 μm, and the distance N is a sum of a width of a micro-lens 10 and the width G of a sub-pixel gap.

Accordingly, a width M of a gap between sub-pixel islands 130 with different color in different rows is 20 μm. This is determined by the requirement that a spacing of the sub-pixel islands with different color is ≥20 μm in the process of manufacturing organic light emitting diodes (OLED) by using fine metal masks (FMM).

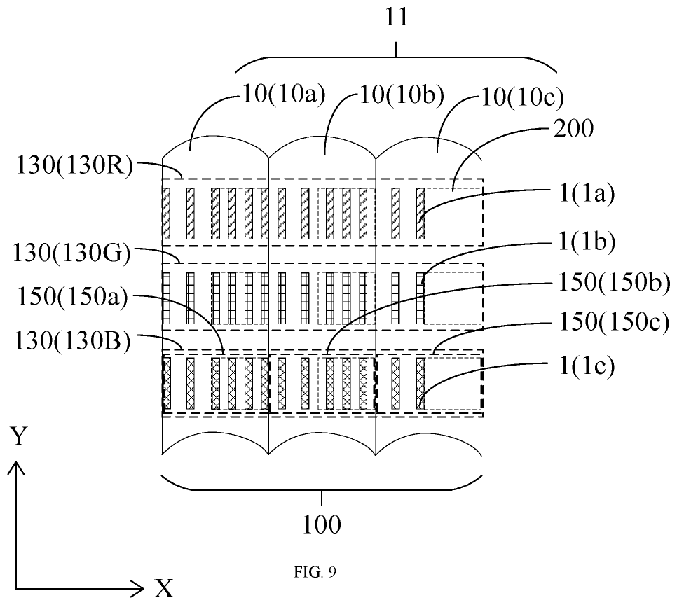

FIG. 9 is a schematic structural diagram of pixel islands 100 in a display panel of another embodiment of the present disclosure. Structures rather than the pixel islands 100 may be same as those in the above embodiments.

As shown in FIG. 9, each of the pixel islands 100 includes sub-pixel islands 130 arranged along the second direction Y (the column direction). In an embodiment shown in the FIG. 9, there are three sub-pixel islands 130: a first sub-pixel island 130R, a second sub-pixel island 130G and a third sub-pixel island 130B. The first sub-pixel island 130R, the second sub-pixel island 130G and the third sub-pixel island 130B are arranged along the column direction Y in sequence. Each of the sub-pixels 1a in the first sub-pixel island 130R is used to emit red light, each of the sub-pixels 1b in the second sub-pixel island 130G is used to emit green light, and each of the sub-pixels 1c in the third sub-pixel island 130B is used to emit blue light.

Correspondingly, sub-pixels 1 included in the first sub-pixel island 130R, the second sub-pixel island 130G and the third sub-pixel island 130B have different light-emitting materials. Sub-pixels 1a of the first sub-pixel island 130R have an organic light-emitting material for emitting red light, sub-pixels 1b of the second sub-pixel island 130G have an organic light-emitting material for emitting green light, sub-pixels 1c of the third sub-pixel island 130B have an organic light-emitting material for emitting blue light. Therefore, when performing evaporation of organic light-emitting materials in the fine metal mask (FMM) evaporation process, three times of evaporation processes are needed, and an organic light-emitting material of one light-emitting color is evaporated for each time.

Layout and arrangement of sub-pixels in the first sub-pixel island 130R, the second sub-pixel island 130G and the third sub-pixel island 130B are same.

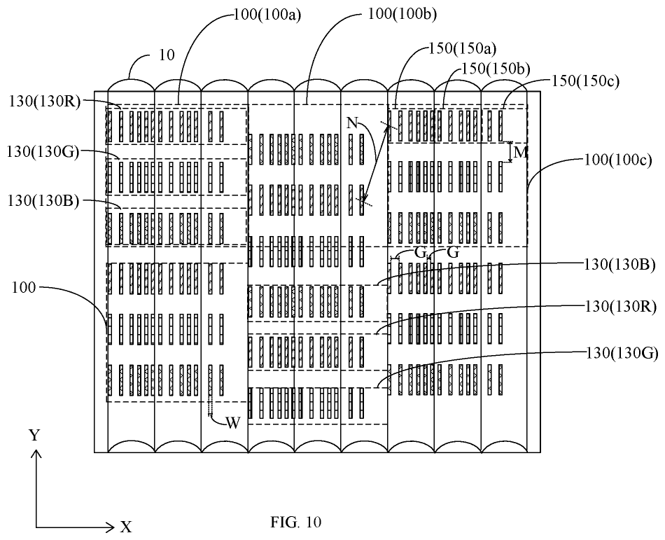

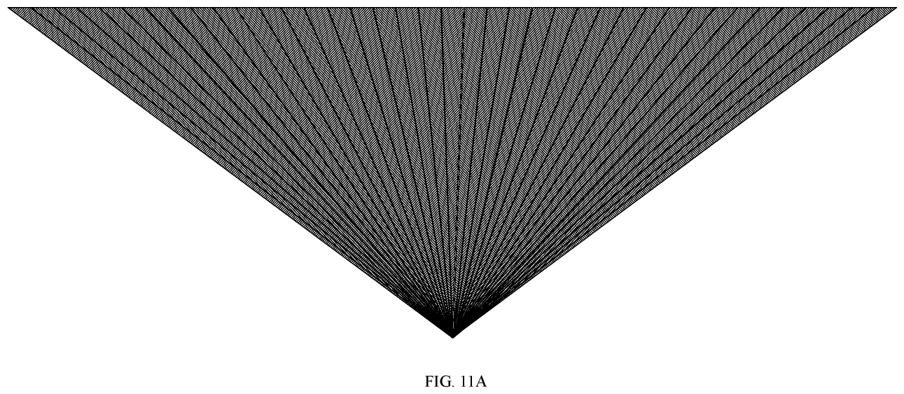

FIG. 10 shows a layout of the pixel islands 100. Referring to FIGS. 9 and 10, each of the sub-pixel islands 130 includes sub-pixel groups 150 arranged along the row direction X. In an embodiment shown in FIG. 10, there are three sub-pixel groups 150: a first sub-pixel group 150a, a second sub-pixel group 150b and a third sub-pixel group 150c. The second sub-pixel group 150b is located between the first sub-pixel group 150a and the third sub-pixel group 150c. A number of sub-pixels 1 may be different in respective sub-pixel groups 150a, 150b and 150c. A number of the sub-pixel groups 150 and a number of the micro-lenses 10 are same. For each of the sub-pixel groups 150, an orthographic projection of the sub-pixel group 150 on the lens array layer 11 falls within a corresponding micro-lens 10.

A difference from above embodiments is that the first sub-pixel group 150a, the second sub-pixel group 150b and the third sub-pixel group 150c are all provided with sub-pixels 1. Since an opaque region needs to be set corresponding to the FMM process, only few sub-pixels 1 are provided in the third sub-pixel group 150c. The opaque region is set in a region of the third sub-pixel group 150c away from the first sub-pixel group 150a and the second sub-pixel group 150b.

In FIG. 9, six sub-pixels 1 and five gaps (each of the gaps is located between two adjacent sub-pixels) are provided in the first sub-pixel group 150a; five sub-pixels 1 and six gaps are provided in the second sub-pixel group 150b; one sub-pixel 1 and three gaps (two gaps between pixels and one opaque region) are provided in the third sub-pixel group 150c.

Positions and widths W of the five sub-pixels 1 in the second sub-pixel group 150b and positions and widths W of the two sub-pixels 1 in the third sub-pixel group 150c are corresponding to positions and widths G of the five gaps in the first sub-pixel group 150a respectively. A first of the sub-pixels 1 in the second sub-pixel group 150b and a first of the sub-pixels 1 in the third sub-pixel group 150c are corresponding to two different regions of a first of the gaps in the first sub-pixel group 150a, and together fill up an entire region of the first of the gaps in the first sub-pixel group 150a. A second of the sub-pixels 1 in the second sub-pixel group 150b and a second of the sub-pixels 1 in the third sub-pixel group 150c are corresponding to two different regions of a second of the gaps in the first sub-pixel group 150a, and together fill up an entire region of the second of the gaps in the first sub-pixel group 150a. A third of the sub-pixels 1 in the second pixel group 150b corresponds to a third of the gaps in the first sub-pixel group 150a, which have corresponding positions and a same width. A fourth of the sub-pixels 1 in the second pixel group 150b corresponds to a fourth of the gaps in the first sub-pixel group 150a, which have corresponding positions and a same width. A fifth of the sub-pixels 1 in the second pixel group 150b corresponds to a fifth of the gaps in the first sub-pixel group 150a, which have corresponding positions and a same width.

A sum of widths W of the five sub-pixels in the second sub-pixel group 150b and widths W of the two sub-pixels 1 in the third sub-pixel group 150c is equal to a sum of widths G of the five gaps in the first sub-pixel group 150a. With such arrangement, after passing through the micro-lens 10, light emitted by the sub-pixels 1 in the second sub-pixel group 150b and the third sub-pixel group 150c can exactly fill in regions corresponding to the five gaps in the first sub-pixel group 150a, so as to achieve continuous 3D display in such regions.

Similarly, positions and widths W of the six sub-pixels 1 in the first sub-pixel group 150a and positions and widths W of the two sub-pixels 1 in the third sub-pixel group 150c are corresponding to and equal to positions and widths G of the six gaps in the second sub-pixel group 150b respectively. A first of the sub-pixels 1 in the first sub-pixel group 150a and a first of the sub-pixels 1 in the third sub-pixel group 150c are corresponding to two different regions of a first of the gaps in the second sub-pixel group 150b, and together fill up an entire region of the first of the gaps in the second sub-pixel group 150b. A second of the sub-pixels 1 in the first sub-pixel group 150a and a second of the sub-pixels 1 in the third sub-pixel group 150c are corresponding to two different regions of a second of the gaps in the second sub-pixel group 150b, and together fill up an entire region of the second of the gaps in the second sub-pixel group 150b.

Similarly, positions and widths W of the six sub-pixels 1 in the first sub-pixel group 150a and positions and widths W of the five sub-pixels 1 in the second sub-pixel group 150b are corresponding to and equal to positions and widths G of the three gaps in the third sub-pixel group 150c respectively. A first of the sub-pixels 1 in the first sub-pixel group 150a and a first of the sub-pixels 1 in the second sub-pixel group 150b are corresponding to two different regions of a first of the gaps in the third sub-pixel group 150c, and together fill up an entire region of the first of the gaps in the third sub-pixel group 150c. A second of the sub-pixels 1 in the first sub-pixel group 150a and a second of the sub-pixels 1 in the second sub-pixel group 150b are corresponding to two different regions of a second of the gaps in the third sub-pixel group 150c, and together fill up an entire region of the second of the gaps in the third sub-pixel group 150c. Third to sixth of the sub-pixels 1 in the first sub-pixel group 150a and third to fifth of the sub-pixels 1 in the second sub-pixel group 150b are corresponding to two different regions of a third of the gaps in the third sub-pixel group 150c, and together fill up an entire region of the third of the gaps in the third sub-pixel group 150c.

Due to process limitation, each of the sub-pixel group 150 cannot emit light continuously. In above embodiments of the present disclosure, sub-pixels 1 of other sub-pixel groups 150 in a same sub-pixel island 130 are used to fill in light-emitting gaps in this sub-pixel group 150, so that the sub-pixel group 150 with discontinuous light emission is equivalent to a pixel structure with continuous light emission. Therefore, effect of continuous 3D display can be achieved.

Two adjacent pixel islands 100 in a same row may not be at a same height in a column direction. A height difference can bring advantages to display effect. As shown in FIG. 10, the first pixel-island 100a and the second pixel island 100b are not at a same height, and a height difference there between may be approximately a half-length of a single sub-pixel. The length of the sub-pixel 1 refers to a length of the sub-pixel 1 extending along the second direction.

In a height direction corresponding to the column direction, a third sub-pixel island 130B of the second pixel island 100b is lower than a first sub-pixel island 130R of the first pixel island 100a, but is higher than a second sub-pixel island 130G of the first pixel island 100a, and is a farthest from a third sub-pixel island 130B of the first pixel island 100a. That is, for two adjacent pixel islands 100 in a same row; sub-pixel islands 130 with a same color are relatively far from each other.

The first pixel islands 100a are arranged in odd columns, and the second pixel islands 100b are arranged in even columns. Each of the first pixel islands 100a includes a first sub-pixel island 130R, a second sub-pixel island 130G and a third sub-pixel island 130B arranged along the column direction in sequence. Each of the second pixel islands 100b includes a third sub-pixel island 130B, a first sub-pixel island 130R and a second sub-pixel island 130G arranged along the column direction in sequence. In addition, the second pixel islands 100b at even columns are lower than the corresponding first pixel islands 100a at odd columns in the column direction by a half-length of a single sub-pixel. With such arrangement, each of the sub-pixel islands overlap, in the height direction, with two sub-pixel islands with different color in an adjacent pixel island, and is far away from a sub-pixel island with a same color in the adjacent pixel island. By setting the sub-pixel islands in adjacent pixel islands with a same color far away from each other, it is apparently advantageous to the FMM evaporation process.

For example, the third sub-pixel island 130B in even columns overlaps, in the column direction, with the first sub-pixel island 130R and the second sub-pixel island 130G in odd columns, and is far away from the third sub-pixel island 130B in odd columns with a same color. The first sub-pixel island 130R in even columns overlaps, in the column direction, with the second sub-pixel island 130G and the third sub-pixel island 130B in odd columns, and is far away from the first sub-pixel island 130R in odd columns with a same color. The second sub-pixel island 130G in even columns overlaps, in the column direction, with the third sub-pixel island 130B and the first sub-pixel island 130R in odd columns, and is far away from the second sub-pixel island 130G in odd columns with a same color.

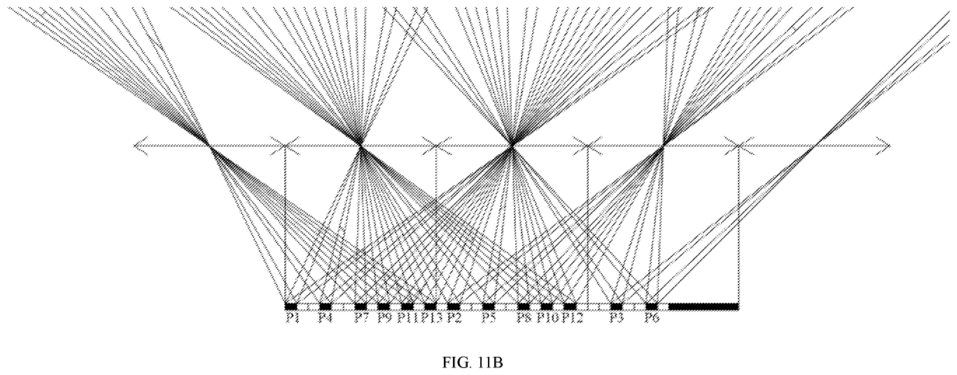

FIGS. 11A and 11B are light path diagrams of the display panels in FIGS. 9 and 10, and FIG. 11B is a partially enlarged diagram of FIG. 11A. As shown in FIGS. 11A and 11B, and with reference to FIGS. 9 and 10, the five sub-pixels P2, P5, P8, P10 and P12 in the second sub-pixel group 150b and the two sub-pixels P3 and P6 in the third sub-pixel group 150c correspondingly fill in the five gaps in the first sub-pixel group 150a (a gap between a sub-pixel P1 and a sub-pixel P4, a gap between a sub-pixel P4 and a sub-pixel P7, a gap between a sub-pixel P7 and a sub-pixel P9, a gap between a sub-pixel P9 and a sub-pixel P11, and a gap between a sub-pixel P11 and a sub-pixel P13). Finally, equal effect of continuous light-emitting is achieved as shown in FIGS. 11A and 11B. Such structural design of the pixel island can increase a light-covering region on edges of the pixel island 100, thereby achieving continuous light-emitting, effectively eliminating Moire patterns, and ensuring display effect.

When the layout of the pixel island array is applied to a 27-inch display panel with a resolution of 4K, same to previous embodiments, a width of each of the pixel islands 100 can be designed to be 156 μm, and correspondingly, a width of each of the micro-lenses 10 is 52 μm, and a width of each of the sub-pixel groups 150 is 52 μm.

Accordingly, a width M of a gap between sub-pixel islands 130 with different color in different rows is 20 μm. This is determined by the requirement that a spacing of the sub-pixel islands with different color is ≥20 μm in the process of manufacturing organic light emitting diodes (OLED) by using fine metal masks (FMM).

Correspondingly, a width G of gaps between adjacent sub-pixels 1 corresponding to a region 200 of the sub-pixel island 130 is 4 μm, while a width G of gaps between adjacent sub-pixels 1 outside the region 200 of the sub-pixel island 130 is 4 μm (the gap width of the sub-pixels is the sub-pixel width) or 8 μm (the gap width of the sub-pixels is double the sub-pixel width). This is determined by the requirement that a spacing of the sub-pixels within an island is ≥4 μm in the process of manufacturing organic light emitting diodes (OLED) by using fine metal masks (FMM).

Accordingly, in the sub-pixel island 130, the width W of each of the sub-pixels 1 is 4 μm.

Accordingly, a distance N between sub-pixels with a same color in adjacent pixel islands 100 is 53.85 μm. The distance N is determined according to a height difference of a half sub-pixel in the column direction of two adjacent pixel islands 100 in a same row.

Those skilled in the art can easily think of other embodiments after considering the disclosure of the specification and embodiments. The present embodiment can be implemented in various forms and should not be limited to the scope of description. The described features, structures or characteristics can be combined in one or more embodiments in any suitable way. The true scope and spirit of the present disclosure is indicated by the claims.

1. A display panel, comprising a pixel array layer and a lens array layer arranged in a stacked manner; wherein
the lens array layer comprises micro-lenses arranged along a first direction;
the pixel array layer comprises pixel islands arranged in an array layout, each of the pixel islands comprises sub-pixel islands arranged along a second direction, each of the sub-pixel islands comprises sub-pixels, and the sub-pixels in a same sub-pixel island have a same luminous color; each of the sub-pixel islands is divided into sub-pixel groups arranged in the first direction;
for two adjacent pixel islands in the first direction, an opaque region is provided in at least one sub-pixel group in an adjacent region of the two adjacent pixel islands, a width of the opaque region in the first direction is greater than a width of a gap between two adjacent sub-pixels in other sub-pixel groups in a same pixel island; and
in a same sub-pixel island, gaps between sub-pixels in a sub-pixel group are correspondingly complemented by the sub-pixels in other sub-pixel groups.

2. The display panel according to claim 1, wherein in a same sub-pixel island, positions of the gaps in one of the sub-pixel groups correspond to positions of the sub-pixels in other two sub-pixel groups; a quantity of and a sum of widths of the gaps in one of the sub-pixel groups are same as a quantity of and a sum of widths of the sub-pixels in the other two sub-pixel groups respectively.

3. The display panel according to claim 1, wherein each of the sub-pixel islands comprises three sub-pixel groups arranged in the first direction: a first sub-pixel group, a second sub-pixel group and a third sub-pixel group, wherein the second sub-pixel group is located between the first sub-pixel group and the third sub-pixel group, and the third sub-pixel group comprises or does not comprise the sub-pixels.

4. The display panel according to claim 3, wherein the opaque region is formed in a region of the third sub-pixel group away from the second sub-pixel group.

5. The display panel according to claim 1, the width of the opaque region≥38 μm.

6. The display panel according to claim 1, wherein each of the pixel islands comprises a first sub-pixel island for emitting red light, a second sub-pixel island for emitting green light and a third sub-pixel island for emitting blue light, wherein the first sub-pixel island, the second sub-pixel island and the third sub-pixel island are arranged along the second direction.

7. The display panel according to claim 6, wherein for any two adjacent pixel islands arranged in the first direction, the first sub-pixel islands of the two adjacent pixel islands are at a same height, the second sub-pixel islands of the two adjacent pixel islands are at a same height, and the third sub-pixel islands of the two adjacent pixel islands are at a same height.

8. The display panel according to claim 6, wherein for any two adjacent pixel islands arranged in the first direction and denoted as a first pixel island and a second pixel island, any two of the sub-pixel islands in the first pixel island and the second pixel island are not at a same height, and a sub-pixel island in the first pixel island is far away from a sub-pixel island with a same color in the second pixel island in a height direction.

9. The display panel according to claim 8, wherein the first pixel islands are arranged in odd columns, and the second pixel islands are arranged in even columns;
each of the first pixel islands comprises the first sub-pixel island, the second sub-pixel island and the third sub-pixel island arranged in sequence along a column direction, and each of the second pixel islands comprises the third sub-pixel island, the first sub-pixel island and the second sub-pixel island arranged in sequence along the column direction; and
the second pixel islands at even columns are lower than the corresponding first pixel islands at odd columns in the column direction by a half-length of a single sub-pixel.

10. The display panel according to claim 1, wherein in a same pixel island, a width of a gap between two adjacent sub-pixels is equal or not equal to a width of a sub-pixel.

11. The display panel according to claim 10, the width of the gap between two adjacent sub-pixels≥4 μm.

12. The display panel according to claim 1, wherein a material of the micro-lens comprises a low refractive index resin and a high refractive index resin, wherein the high refractive index resin is closer to the pixel array layer than the low refractive index resin.

13. The display panel according to claim 1, wherein the display panel further comprises a pad layer, and the pad layer is between the pixel array layer and the lens array layer.

14. The display panel according to claim 1, wherein sub-pixels in the pixel islands for emitting lights of different color are made up of different organic light-emitting materials.

15. A display apparatus, wherein the display apparatus comprises the display panel according to claim 1.

16. The display panel according to claim 1, wherein for each of the sub-pixel groups, an orthographic projection of the sub-pixel group on the lens array layer falls within a corresponding micro lens.
